(19) United States
(12) Patent Application Publication
(10) Pub. No.: US 2024/0228518 A1
(43) Pub. Date: Jul. 11, 2024

(54) NOVEL ORGANOTIN SILICATE COMPOUNDS, PREPARATION METHODS THEREOF AND PHOTORESIST COMPOSITION CONTAINING THE SAME

(71) Applicants: JSI SILICONE CO., Seongnam-si (KR); INDUSTRY FOUNDATION OF CHONNAM NATIONAL UNIVERSITY, Gwangju (KR)

(72) Inventors: Yu Sun WON, Goyang-si (KR); Seung Hwan KANG, Seoul (KR); Hyun Tae JUNG, Hanam-si (KR); Hyun Dam JEONG, Gwangju (KR); Ji Young BANG, Gwangju (KR)

(73) Assignees: JSI SILICONE CO., Seongnam-si (KR); INDUSTRY FOUNDATION OF CHONNAM NATIONAL UNIVERSITY, Gwangju (KR)

(21) Appl. No.: 18/395,922

(22) Filed: Dec. 26, 2023

(30) Foreign Application Priority Data
Dec. 26, 2022 (KR) 10-2022-0184715
Dec. 18, 2023 (KR) 10-2023-0184108

(51) Int. Cl. C07F 7/22; G03F 7/004

(52) U.S. Cl. CPC C07F 7/2224; G03F 7/0042

(57) ABSTRACT

Provided are a novel organostannyl silicate compound, a method for preparing the same, a photoresist composition including the organostannyl silicate compound according to the present disclosure, and a method for forming a photoresist pattern using the composition. The organostannyl silicate compound of the present disclosure is industrially very useful, since the compound may implement a photoresist composition having excellent light sensitivity and etching resistance and a high-quality semiconductor device may be manufactured using the composition.

### CROSS-REFERENCE TO RELATED APPLICATIONS

This application claims the benefit of priority under 35 U.S.C. § 119 to Korean Patent Application Nos. 10-2022-0184715, filed Dec. 26, 2022, and 10-2023-0184108, filed Dec. 18, 2023, the contents of which is incorporated herein by reference in its entirety.

### TECHNICAL FIELD

The following disclosure relates to an organostannyl silicate compound having a novel structure and a method for preparing the same, and more particularly, to an organostannyl silicate compound which is included in a photoresist composition to allow the composition to have excellent light sensitivity to extreme ultraviolet rays and etching resistance, and a method for efficiently preparing the same.

### BACKGROUND

The statements in this section merely provide background information related to the present disclosure and may not constitute prior art.

Among semiconductor manufacturing processes, a photolithography process which draws a semiconductor circuit may be compared to printing which uses light to develop photographs. In the photolithography process, a photoresist material is applied on a semiconductor substrate and light is allowed to pass through a mask with a circuit pattern engraved, thereby drawing a circuit, and then a developer is treated on a semiconductor substrate to form a circuit pattern by an etching process of selectively removing a light-exposed area and a non-exposed area.

As a lithography light source, I-line (365 nm), KrF (248 nm), and ArF (193 nm) have been mainly used. Due to the high integration of a semiconductor, formation of ultrafine patterns is demanded, and for this, the wavelength of a light source is gradually becoming shorter. In particular, as a next-generation light source for manufacturing an ultra-highly integrated semiconductor, an extreme ultraviolet (EUV) having a wavelength of 13.5 nm is emerging.

In an extreme ultraviolet lithography process, photons having a strong energy of 92 eV (13.5 nm) are irradiated, and unlike a lithography process of a conventional light source which expresses a dissolution contrast of a photoresist by a photochemical reaction, the dissolution contrast of a photoresist which is expressed by a radiochemical reaction by secondary electrons produced after extreme ultraviolet irradiation is used.

A resolution (R) which may be made by a photolithography process refers to a minimum line width which may be transferred to a substrate, and as the resolution is smaller, it is more favorable for small pattern formation and the resolution may be represented by R=k₁λ/NA′ wherein k₁ is a process coefficient, NA is the numerical aperture of a lens, and A is a wavelength of used light. In order to make small patterns, the wavelength of light has been reduced.

The performance of a photoresist is largely evaluated as resolution (R), line edge roughness (L), and sensitivity (S), and an explicit relationship among RLS parameters is also expressed as a z-parameter. A z-parameter is (resolution)³×(line edge roughness)²×(sensitivity) (Sci Rep 5, 9235 (2015)). As the value is smaller, the performance of a photoresist is better.

In order to manufacture a semiconductor thin film having a high-quality circuit patterns even under low light irradiation in a photolithography process, development of a photoresist material having excellent light sensitivity and etching resistance is needed. As an element having excellent light sensitivity, elements such as bismuth, palladium, platinum, and tin have been reported (US Patent Publication No. 2019-0153001 A1, May 23, 2019). Among them, a compound including tin has excellent properties of absorbing extreme ultraviolet rays.

Silicate refers to an oxide of silicon, and when it is included in a compound structure, excellent etching resistance may be implemented, but since silicate has low light sensitivity to extreme ultraviolet rays, it is difficult to use it as a photoresist material for extreme ultraviolet rays. In order to overcome the problem, the present inventors synthesized a photoresist material satisfying both excellent light sensitivity and etching resistance in which a mole ratio of silicon and tin present in the compound is 1:4, and confirmed that a photoresist pattern may be formed with a small thickness even in an ultrafine pattern, thereby completing the present disclosure.

### SUMMARY

An embodiment of the present disclosure is directed to providing a novel organostannyl silicate compound and a method for preparing the same.

Another embodiment of the present disclosure is directed to providing a photoresist composition including the organostannyl silicate compound according to the present disclosure and a method for forming a photoresist pattern using the same.

Still another embodiment of the present disclosure is directed to implement a photoresist composition having excellent light sensitivity and etching resistance by including an organostannyl silicate compound and provide a high-quality semiconductor device manufactured using the same.

In one general aspect, an organostannyl silicate compound represented by the following Chemical Formula 1 is provided:

Si[OSn(R¹R²R³)]₄ [Chemical Formula 1]
wherein
R¹ to R³ are independently of one another substituted or unsubstituted C6-C12 aryl, straight-chain or branched-chain C1-C10 alkyl, C3-C7 cycloalkyl, C2-C6 alkenyl, C6-C12 arylC1-C5 alkyl, hydroxyl, C1-C5 alkoxy, C1-C5 alkylcarbonyloxy, or halogen.
R¹ to R³ may be phenyl.
R¹ to R³ may be independently of one another C1-C5 alkylcarbonyloxy.
R¹ to R³ may be independently of one another straight-chain or branched-chain C1-C7 alkyl.

In another general aspect, a photoresist composition includes the organostannyl silicate compound described above.

A photoresist of the photoresist composition may be a photoresist for extreme ultraviolet rays.

In another general aspect, a method for forming a photoresist pattern includes: (a) applying the photoresist composition described above on a substrate to form a thin film and heating the thin film; (b) exposing the thin film to light; (c) heating the light-exposed thin film; and (d) developing the thin film using a developing solution.

In still another general aspect, a semiconductor device manufactured by the method for forming a photoresist pattern described above is provided.

Other features and aspects will be apparent from the following detailed description, the drawings, and the claims. It should be understood that the description and specific examples are intended for purposes of illustration only and are not intended to limit the scope of the present disclosure. Further areas of applicability will become apparent from the description provided herein.

### BRIEF DESCRIPTION OF THE DRAWINGS

In order that the disclosure may be well understood, there will not be described various forms thereof, given by way of example, reference being made to the accompanying drawings, in which:

FIG. 1 shows results of a MALDI-TOF spectrum of a tetrakis(triphenylstannyl) silicate compound prepared in Example 1;

FIG. 2 shows results of a FD-MS spectrum of the tetrakis(triphenylstannyl) silicate compound prepared in Example 1;

FIG. 3 shows results of ¹H, ¹³C, ²⁹Si, and ¹¹⁹Sn-NMR spectra of the tetrakis(triphenylstannyl) silicate compound prepared in Example 1;

FIG. 4 shows results of a XPS spectrum of the tetrakis(triphenylstannyl) silicate compound prepared in Example 1;

FIG. 5 shows results of a FT-IR spectrum of the tetrakis(triphenylstannyl) silicate compound prepared in Example 1;

FIG. 6 shows results of a SC-XRD spectrum of the tetrakis(triphenylstannyl) silicate compound prepared in Example 1;

FIG. 7 shows results of a 1H-NMR spectrum of a tetrakis(triacetoxystannyl) silicate compound prepared in Example 14;

FIG. 8 shows results of a MALDI-TOF spectrum of the tetrakis(triacetoxystannyl) silicate compound prepared in Example 14;

FIG. 9 shows results of photoresist electron beam sensitivity of tetrakis(triphenylstannyl) silicate of Example 20;

FIG. 10 shows results of photoresist electron beam sensitivity of tetrakis(trimethylstannyl) silicate of Example 21;

FIG. 11 shows results of photoresist electron beam sensitivity of tetrakis(triacetoxystannyl) silicate of Example 22; and

FIG. 12 shows results of photoresist line patterning of tetrakis(triacetoxystannyl) silicate of Example 23.

The drawings described herein are for illustration purposes only and are not intended to limit the scope of the present disclosure in any way.

### DETAILED DESCRIPTION

Hereinafter, an organostannyl silicate compound, a method for preparing the same, a photoresist composition including the same, and a method for forming a photoresist pattern using the same.

The singular form used in the present disclosure may be intended to also include a plural form, unless otherwise indicated in the context.

In addition, the numerical range used in the present specification includes all values within the range including the lower limit and the upper limit, increments logically derived in a form and span of a defined range, all double limited values, and all possible combinations of the upper limit and the lower limit in the numerical range defined in different forms. Unless otherwise particularly defined in the present specification, values which may be outside a numerical range due to experimental error or rounding off of a value are also included in the defined numerical range.

Furthermore, throughout the specification, unless explicitly described to the contrary, “comprising” any constituent elements will be understood to imply further inclusion of other constituent elements rather than exclusion of other constituent elements.

In the present specification, “room temperature” refers to a temperature of 20±5° C.

The terms “substituent”, “radical”, “group”, “moiety”, and “fragment” in the present specification may be used interchangeably.

The term “C_{A}-C_{B}” in the present specification refers to “the number of carbon atoms being A or more and B or less”.

The term “alkyl” in the present specification refers to a monovalent straight-chain or branched-chain saturated hydrocarbon radical composed of only carbon and hydrogen atoms. The alkyl may have 1 to 10 carbon atoms, 1 to 7 carbon atoms, or 1 to 4 carbon atoms. The alkyl includes methyl, ethyl, propyl, isopropyl, butyl, isobutyl, t-butyl, pentyl, hexyl, ethylhexyl, and the like, but is not limited thereto.

The term “cycloalkyl” in the present specification is a monovalent saturated or unsaturated carbocyclic radical composed of one or more rings, and is not an aromatic group. The cycloalkyl may have 3 to 10, preferably 3 to 8, and more preferably 5 to 7 carbon atoms. The cycloalkyl includes, as an example, cyclopropyl, cyclobutyl, cyclopentyl, cyclohexyl, and cycloheptyl, but is not limited thereto.

The term “alkenyl” in the present specification refers to a straight-chain or branched-chain unsaturated hydrocarbon radical containing a carbon-carbon double bond. The alkenyl may have 2 to 10 carbon atoms, 2 to 8 carbon atoms, or 2 to 6 carbon atoms. The alkenyl includes, as an example, ethenyl, propenyl, allyl, butenyl, 4-methylbutenyl, and the like, but is not limited thereto.

The term “alkoxy” in the present specification refers to an alkyl-O—* radical, in which “alkyl” is as described above. A specific example thereof includes methoxy, ethoxy, isopropoxy, butoxy, isobutoxy, t-butoxy, and the like, but is not limited thereto.

The term “alkylcarbonyloxy” in the present specification refers to an alkyl-C(═O)—O—* radical, in which “alkyl” is as described above. An example of the alkylcarbonyloxy radical includes methylcarbonyloxy, ethylcarbonyloxy, isopropylcarbonyloxy, propylcarbonyloxy, butylcarbonyloxy, isobutylcarbonyloxy, t-butylcarbonyloxy, and the like, but is not limited thereto. In addition, the term “acetoxy” in the present specification has a meaning equivalent to methylcarbonyloxy.

The term “halogen” in the present specification refers to a halogen group element, and for example, includes fluoro, chloro, bromo, and iodo.

The term “aryl” in the present specification refers to a monovalent organic radical of an aromatic ring derived from an aromatic hydrocarbon by removal of one hydrogen, which includes a single- or fused ring system containing appropriately 4 to 7, preferably 5 or 6 ring atoms in each ring, and even a form in which a plurality of aryls is connected by a single bond. A specific example thereof includes phenyl, naphthyl, biphenyl, anthryl, indenyl, fluorenyl, and the like, but is not limited thereto.

The term “arylalkyl” in the present specification refers to an alkyl radical substituted by at least one aryl, in which “alkyl” and “aryl” are as defined above. A specific example of the arylalkyl includes benzyl and the like, but is not limited thereto.

The term “substituted aryl” in the present specification refers to an aryl group having one or more substituent groups attached thereto. A specific example thereof includes an aryl group having any one or more substituents selected from deuterium, hydroxy, halogen, formyl (—CHO), carboxyl, cyano, nitro, amino, alkyl, haloalkyl, alkoxy, haloalkoxy, alkenyl, alkynyl, alkylcarbonyl, alkoxycarbonyl, alkylcarbonyloxy, alkenylcarbonyloxy, alkynylcarbonyloxy, aminocarbonyl, alkylcarbonylamino, alkenylcarbonylamino, alkynylcarbonylamino, alkylthio, alkylsilyl, alkenylsilyl, alkynylsilyl, arylsilyl, arylalkyl, arylalkenyl, arylalkynyl, cycloalkyl, cycloalkenyl, amino, alkylamino, dialkylamino, heteroaryl, heterocyclyl, heteroarylalkyl, heterocycloalkyl, and the like, but is not limited thereto.

The term “acetoxy” in the present specification has a meaning equivalent to “methylcarbonyloxy”.

The present disclosure provides an organostannyl silicate compound having a novel structure represented by the following Chemical Formula 1:

Si[OSn(R¹R²R³)]₄ [Chemical Formula 1]
wherein
R¹ to R³ are independently of one another substituted or unsubstituted C6-C12 aryl, straight-chain or branched-chain C1-C10 alkyl, C3-C7 cycloalkyl, C2-C6 alkenyl, C6-C12 arylC1-C5 alkyl, hydroxyl, C1-C5 alkoxy, C1-C5 alkylcarbonyloxy, or halogen.

The organostannyl silicate compound of the present disclosure has a silicate structure having a SiO₄ molecular skeleton, in which an organostannyl substituent is introduced to each oxygen atom, thereby preparing a photoresist material which has a mole ratio of silicon and tin in the molecule of 1:4 to satisfy both excellent light sensitivity and etching resistance.

As an example, in Chemical Formula 1, R¹ to R³ may be phenyl.

As an example, in Chemical Formula 1, R¹ to R³ may be independently of one another C1-C5 alkylcarbonyloxy. Specifically, they may be methylcarbonyloxy or ethylcarbonyloxy, and more specifically, they may be identically methylcarbonyloxy.

As an example, in Chemical Formula 1, R¹ to R³ may be independently of one another straight-chain or branched-chain C1-C7 alkyl. Specifically, they may be methyl, ethyl, propyl, or t-butyl, preferably, they may be t-butyl.

In addition, the present disclosure provides a photoresist composition including the organostannyl silicate compound described above.

Since the organostannyl silicate compound according to the present disclosure includes a tin atom having a large photoionization cross-sectional area to short wavelength light such as extreme ultraviolet rays, secondary electrons occur in the tin atom to promote formation of a silicon radical to improve photoresist sensitivity.

The photoresist composition according to the present disclosure may be a photoresist composition for extreme ultraviolet rays (EUV).

The photoresist composition including the organostannyl silicate compound according to the present disclosure has excellent extreme ultraviolet light sensitivity and etching resistance, whereby a photoresist pattern using the composition may be formed with a very thin thickness even in an ultrafine pattern, and also a high-quality photoresist pattern having excellent resolution and sensitivity may be formed.

A solvent used in the photoresist composition according to the present disclosure may be any solvent in which the organostannyl silicate compound is dissolved, and as an example, may be one or two or more selected from the group consisting of chloroform, ethyl lactate, and tetrahydrofuran.

The photoresist composition according to the present disclosure may include the organostannyl silicate compound at a weight ratio of 0.1 to 50. The organostannyl silicate compound may be included at a weight ratio of preferably 0.5 to 30, more preferably 0.5 to 5. When the weight ratio range is satisfied, a photoresist pattern having better resolution and sensitivity may be formed.

The photoresist composition according to the present disclosure may include an organostannyl silicate compound in which R¹ to R³ in Chemical Formula 1 are independently of one another C1-C5 alkylcarbonyloxy and an acetic acid, and preferably, the C1-C5 alkylcarbonyloxy may be acetoxy. The photoresist composition satisfying the combination has a reduced hydrolysis rate of an acetoxy group of the organostannyl silicate compound and may have improved stability in water.

As an example, the acetic acid may be included at a weight ratio of 0.1 to 50 of the photoresist composition. The acetic acid may be included at a weight ratio of preferably 1.0 to 30, more preferably 10 to 30.

In addition, the present disclosure provides a method for forming a photoresist pattern including: (a) applying the photoresist composition described above on a substrate to form a thin film and heating the thin film; (b) exposing the thin film to light; (c) heating the light-exposed thin film; and (d) developing the thin film using a developing solution.

Specifically, the step of (c) heating the thin film is a post apply bake (PAB) process and may be performed at 60° C. to 150° C., preferably 80° C. to 120° C., and thus, the solvent included in the photoresist composition may be removed to improve adhesive strength between a photoresist film and a substrate.

Specifically, the photoresist composition may be applied on a substrate using any method without limitation as long as the method is known in the art, and as an example, may be applied using a method such as spin coating, dipping, roller coating, bar coating, spray coating, inkjet printing, and screen printing, but is not limited thereto.

The photoresist composition may be applied on a substrate by a spin coating method. Herein, a thickness of a photoresist film to be desired may be adjusted based on a spinner speed and a coating execution time. As an example, spin coating may be performed at a speed of 1000 rpm to 5000 rpm, specifically 2000 rpm to 4000 rpm for 10 seconds to 60 seconds, specifically 20 seconds to 40 seconds, but is not limited thereto.

As an example, in the step of (a) of the method for forming a photoresist pattern, the heating of a thin film is a post exposure bake (PEB) process and may be performed at 60° C. to 150° C., preferably 80° ° C. to 120° C., and thus, a solubility difference in a developing solution between a light-exposed area and a non-exposed area may be increased.

As an example, the step of (c) light-exposing the thin film may be performed by extreme ultraviolet rays, I-line, KrF, ArF, DUV, VUV (vacuum ultra violet), X-rays, electron beams, or ion beams, and extreme ultraviolet rays or electron beams may be preferred, but the present disclosure is not necessarily limited thereto.

As an example, the step of (d) using a developing solution to develop the thin film may be specifically performed using a developing solution including a quaternary ammonium salt, and a specific example of the quaternary ammonium salt may be tetramethyl ammonium hydroxide (TMAH), tetrabutylammonium hydroxide (TBAH), tetrapropylammonium hydroxide (TPAH), tetraethylammonium hydroxide (TEAH), or a mixture thereof. The developing solution may include 1 wt % to 10 wt %, specifically 1 wt % to 5 wt % of a quaternary ammonium salt, but is not necessarily limited thereto.

In addition, the present disclosure provides a semiconductor device including a photoresist pattern formed by the method for forming a photoresist pattern described above, and since the semiconductor device includes the photoresist pattern formed with excellent resolution and sensitivity by the method described above, a higher quality semiconductor device may be implemented.

A first embodiment of a method for preparing an organostannyl silicate compound according to the present disclosure may include reacting an ammonium compound represented by the following Chemical Formula 2 and tin chloride represented by Chemical Formula 3 to prepare an organostannyl silicate compound of Chemical Formula 4:

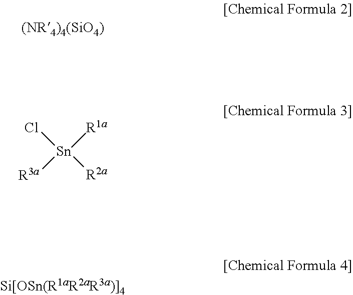

wherein
R^{1a} to R^{3a} are independently of one another substituted or unsubstituted C6-C12 aryl, straight-chain or branched-chain C1-C10 alkyl, C3-C7 cycloalkyl, C2-C6 alkenyl, or C6-C12 arylC1-C5 alkyl; and
R′ is straight-chain or branched-chain C1-C5 alkyl, substituted or unsubstituted C6-C12 aryl, or C6-C12 arylC1-C5 alkyl.

Herein, the compound of Chemical Formula 3 may be used in an excessive amount with respect to the compound of Chemical Formula 2.

A second embodiment of the method for preparing an organostannyl silicate compound according to the present disclosure may include reacting an ammonium compound represented by the following Chemical Formula 2 and tin chloride represented by Chemical Formula 3 to prepare an organostannyl silicate compound of Chemical Formula 4; and
reacting the compound of Chemical Formula 4 and tin chloride represented by the following Chemical Formula 5 to prepare an organostannyl silicate compound of Chemical Formula 6:

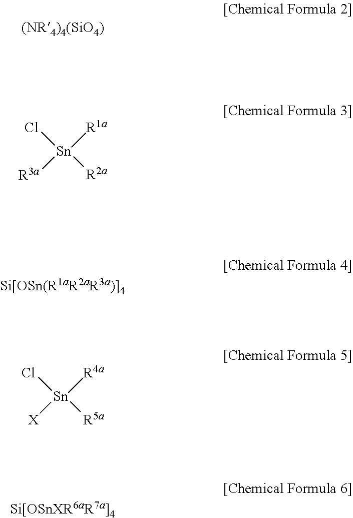

wherein
R^{1a} to R^{3a} are independently of one another substituted or unsubstituted C6-C12 aryl, straight-chain or branched-chain C1-C10 alkyl, C3-C7 cycloalkyl, C2-C6 alkenyl, or C6-C12 arylC1-C5 alkyl;
R^{4a} to R^{7a} are independently of one another unsubstituted C6-C12 aryl, straight-chain or branched-chain C1-C10 alkyl, C3-C7 cycloalkyl, C2-C6 alkenyl, C6-C12 arylC1-C5 alkyl, or halogen;
R′ is straight-chain or branched-chain C1-C5 alkyl, substituted or unsubstituted C6-C12 aryl, or C6-C12 arylC1-C5 alkyl; and
X is a halogen.

Herein, the compound of Chemical Formula 3 may be used in an excessive amount with respect to the compound of Chemical Formula 2. In addition, the tin chloride of Chemical Formula 5 may be used in an excessive amount of 1.0 mol or more, preferably 5.0 mol or more, and more preferably 10.0 mol or more with respect to 1.0 mol of the organostannyl silicate compound of Chemical Formula 4.

In an exemplary embodiment, when R^{4a} and/or R^{5a} of the second embodiment of the preparation method is halogen, R^{6a} and/or R^{7a} of Chemical Formula 6 may be halogen.

A third embodiment of the method for preparing an organostannyl silicate compound according to the present disclosure may include reacting an ammonium compound represented by the following Chemical Formula 2 and tin chloride represented by Chemical Formula 3 to prepare an organostannyl silicate compound of Chemical Formula 4; and
reacting the compound of Chemical Formula 4 and an organic acid represented by the following Chemical Formula 7 to prepare an organostannyl silicate compound of Chemical Formula 8:

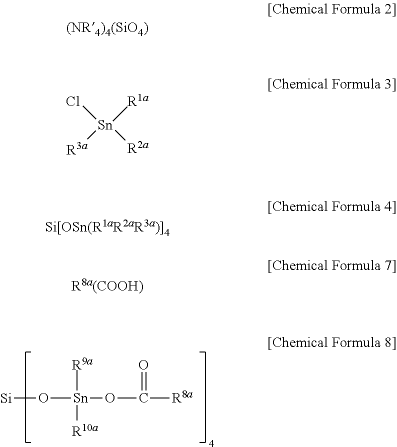

wherein
R^{1a} to R^{3a} are independently of one another substituted or unsubstituted C6-C12 aryl, straight-chain or branched-chain C1-C10 alkyl, C3-C7 cycloalkyl, C2-C6 alkenyl, or C6-C12 arylC1-C5 alkyl;
R^{8a} is straight-chain or branched-chain C1-C10 alkyl;
R^{9a} and R^{10a} are independently of each other substituted or unsubstituted C6-C12 aryl, straight-chain or branched-chain C1-C10 alkyl, C3-C7 cycloalkyl, C2-C6 alkenyl, C6-C12 arylC1-C5 alkyl, or C1-C5 alkylcarbonyloxy; and
R′ is straight-chain or branched-chain C1-C5 alkyl, substituted or unsubstituted C6-C12 aryl, or C6-C12 arylC1-C5 alkyl.

Herein, the compound of Chemical Formula 3 may be used in an excessive amount with respect to the compound of Chemical Formula 2. The organic acid of Chemical Formula 7 may be used in an excessive amount of 1.0 mol or more with respect to 1.0 mol of the organostannyl silicate compound of Chemical Formula 4.

Herein, when the organic acid of Chemical Formula 7 of the third embodiment of the preparation method is added at 5.0 mol or more, preferably 10.0 mol or more, and more preferably 12.0 mol or more with respect to 1.0 mol of the organostannyl silicate compound of Chemical Formula 4 and reacts, R⁹ and/or R¹⁰ of Chemical Formula 8 may be C1-C10 alkylcarbonyloxy.

A fourth embodiment of the method for preparing an organostannyl silicate compound according to the present disclosure may include reacting an ammonium compound represented by the following Chemical Formula 2 and tin chloride represented by Chemical Formula 3 to prepare an organostannyl silicate compound of Chemical Formula 4;

reacting the compound of Chemical Formula 4 and tin chloride represented by the following Chemical Formula 5 to prepare an organostannyl silicate compound of Chemical Formula 6; and reacting the compound of Chemical Formula 6 and a compound represented by the following Chemical Formula 9 to prepare a compound of Chemical Formula 10:

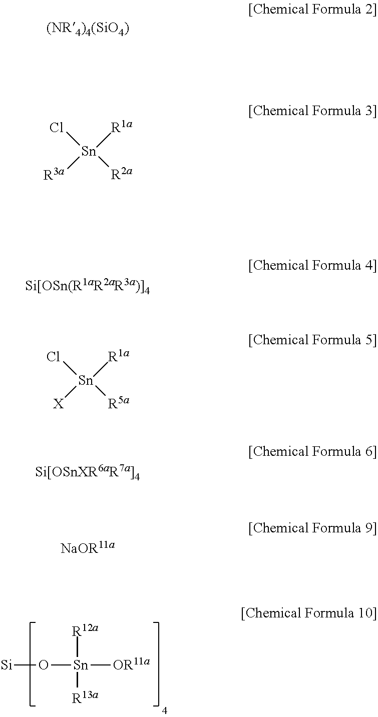

wherein
R^{1a} to R^{3a} are independently of one another substituted or unsubstituted C6-C12 aryl, straight-chain or branched-chain C1-C10 alkyl, C3-C7 cycloalkyl, C2-C6 alkenyl, or C6-C12 arylC1-C5 alkyl;
R^{4a} to R^{7a} are independently of one another unsubstituted C6-C12 aryl, straight-chain or branched-chain C1-C10 alkyl, C3-C7 cycloalkyl, C2-C6 alkenyl, C6-C12 arylC1-C5 alkyl, or halogen;
R^{11a} is hydrogen or straight-chain or branched-chain C1-C10 alkyl;
R^{12a} and R^{13a} are independently of each other substituted or unsubstituted C6-C12 aryl, hydroxyl, straight-chain or branched-chain C1-C10 alkyl, C3-C7 cycloalkyl, C2-C6 alkenyl, C6-C12 arylC1-C5 alkyl, or C1-C5 alkoxy;
R′ is straight-chain or branched-chain C1-C5 alkyl, substituted or unsubstituted C6-C12 aryl, or C6-C12 arylC1-C5 alkyl; and
X is a halogen.

Herein, the compound of Chemical Formula 3 may be used in an excessive amount with respect to the compound of Chemical Formula 2. The tin chloride of Chemical Formula 5 may be used in an excessive amount of 1.0 mol or more, preferably 5.0 mol or more, and more preferably 10.0 mol or more with respect to 1.0 mol of the organostannyl silicate compound of Chemical Formula 4.

In an exemplary embodiment, when R^{6a} and/or R^{7a} of the fourth embodiment of the preparation method is/are halogen, R^{12a} and/or R^{13a} may be hydroxyl or C1-C10 alkoxy.

In addition, the compound of Chemical Formula 9 may be used in an excessive amount of 1.0 mol or more, preferably 3.0 mol or more with respect to 1.0 mol of the organostannyl silicate compound of Chemical Formula 6.

In the preparation method according to an exemplary embodiment, halogen may be preferably Cl, substituted or unsubstituted C6-C12 aryl may be more preferably phenyl or tolyl, and still more preferably, phenyl, since a desired compound may be prepared with more improved reactivity.

As an example, in the preparation method, a reaction temperature may be 10° C. to 250° C., preferably 50° C. to 200° C., and when the reaction temperature is higher than a boiling point of a solvent, a reaction vessel may be pressurized to synthesize the compound.

As an example, in the preparation method, a pressure may be 0 atm to 10 atm, preferably 0 to 5 atm, and more preferably 0 to 3 atm.

In the preparation method, the organostannyl represented by Chemical Formula 3 or 5 may be prepared by a known synthesis method (Phys. Chem. Chem. Phys., 2019, 21, 6732-6742).

In the preparation method, when the reaction is completed, the solvent is distilled under reduced pressure, and then a target may be separated and purified by a common method such as column chromatography and recrystallization.

The preparation method may be performed in a common organic solvent, but as an example, may be performed in one or two or more organic solvents selected from the group consisting of diethyl ether, diisopropyl ether, ethyl acetate, propylene carbonate, dimethoxyethane (DME), tetrahydrofuran (THF), hexane, toluene, benzene, 1,4-dioxane, pentane, cyclopentane, heptane, cyclohexane, xylene, methylisobutylketone, propylene glycol, methyl ether acetate, and propylene glycol methyl ether, and specifically, tetrahydrofuran (THF) may be used.

In the preparation method, the ammonium compound represented by Chemical Formula 2 may be prepared by reacting any one compound selected from the group consisting of tetramethoxysilane, tetraethoxysilane, fumed silica, and tetramethylammonium silicate (Si(OH)₂(ONMe₄)₂ and tetramethylammonium hydroxide (NMe₄OH).

The organostannyl silicate compound prepared by the preparation method according to the present disclosure is a photoresist material having excellent light sensitivity and etching resistance, and may be very useful in a semiconductor industry.

Hereinafter, the constitution of the present disclosure will be described in more detail by the examples, but the following examples are for better understanding of the present disclosure, and the scope of the present disclosure is not limited thereto.

### [Preparation Example 1] Synthesis 1 of Tetrakis Ammonium Silicate Compound (N(Me₄)₄(SiO₄))

A mechanical stirrer and a refluxer were installed in a 50 ml round bottom flask having two inlets, 0.2 g (1.30 mmol) of tetramethoxysilane and 1.9 g (5.20 mmol) of 25% a tetramethylammonium hydroxide aqueous solution were added thereto, and a reaction was performed for 4 hours while stirring at room temperature to obtain a tetrakis(tetramethylammonium) silicate solution.

### [Preparation Example 2] Synthesis 2 of Tetrakis Ammonium Silicate Compound (N(Me₄)₄(SiO₄))

A tetrakis(tetramethylammonium) silicate solution was obtained in the same manner as in Preparation Example 1, except that 0.3 g (1.30 mmol) of tetraethoxysilane was used instead of tetramethoxysilane.

### [Preparation Example 3] Synthesis 3 of Tetrakis Ammonium Silicate Compound (N(Me₄)₄(SiO₄))

A tetrakis(tetramethylammonium) silicate solution was obtained in the same manner as in Preparation Example 1, except that 0.1 g (1.30 mmol) of fumed silica was used instead of tetramethoxysilane.

### [Preparation Example 4] Synthesis 4 of Tetrakis Ammonium Silicate Compound (N(Me₄)₄(SiO₄))

A tetrakis(tetramethylammonium) silicate solution was obtained in the same manner as in Preparation Example 1, except that 1.7 g (1.12-1.40 mmol) of a 16-20% tetramethylammonium silicate aqueous solution (Gelest, USA) and 0.9 g (2.59 mmol) of a 25% tetramethylammonium hydroxide aqueous solution were used instead of tetramethoxysilane.

### [Example 1] Synthesis of tetrakis(triphenylstannyl) Silicate Compound

A mechanical stirrer and a refluxer were installed in a 100 ml round bottom flask having two inlets and the flask was mounted on a heating mantle. A solution of 2.0 g (5.19 mmol) of triphenylchlorotin dissolved in 50 ml of tetrahydrofuran was added to a reaction vessel, and the reaction was performed for 8 hours while the tetrakis(tetramethylammonium) silicate solution prepared according to Preparation Example 1 was slowly added using a dropping funnel and stirred with a stirrer at 75° C. The reaction solution was filtered at 75° C. in a 100 mL round bottom flask having two spouts, and extraction was performed three times using 15 mL of tetrahydrofuran preheated to 50° C. A white solid obtained by distilling the solvent was recrystallized three times with tetrahydrofuran to obtain 1.2 g (0.80 mmol, yield: 61.5%) of a white crystal.

The synthesized product was analyzed by FD-MS, MALDI-TOF, ¹H, ¹³C, ²⁹Si, ¹¹⁹Sn-NMR, XPS, FT-IR, and SC-XRD.

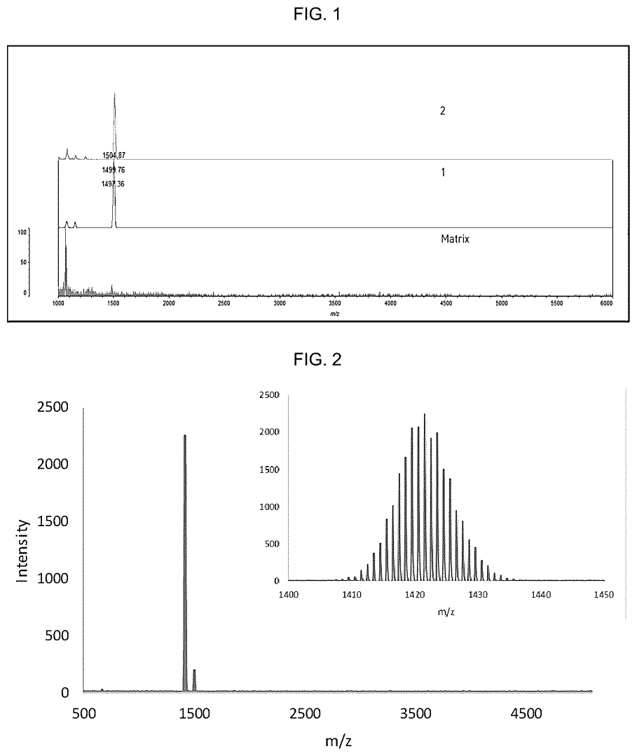

In FIG. 1, a peak at 1497.36 of MALDI-TOF which was consistent with a total molecular weight of the tetrakis(triphenylstannyl) silicate compound and a main peak at 1421 of FD-MS which was consistent with a molecular weight of a tetrakis(triphenylstannyl) silicate compound from which one phenyl group had been removed were confirmed. In addition, in FIG. 2, it was confirmed that tin was included by isotopic distribution of FD-MS.

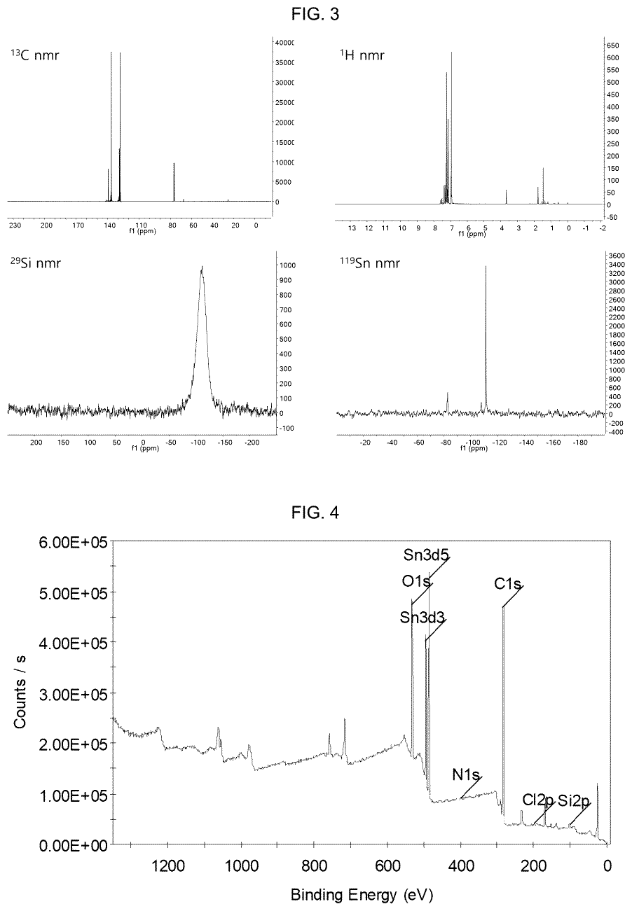

In FIG. 3, ¹H, ¹³C, ²⁹Si, and ¹¹⁹Sn-NMR spectra of the tetrakis(triphenylstannyl) silicate compound is shown. In 13C-NMR, a carbon peak of a phenyl group between 100 and 150 ppm was confirmed, and in 1H-NMR, a hydrogen peak of a phenyl group was confirmed around 7 ppm. Further, in ²⁹Si-NMR, a wide single peak at 109 ppm showing O—SiO₃ was confirmed, and in ¹¹⁹Sn-NMR, a peak of O—Sn-Ph₃ at 111 ppm was confirmed.

In addition, an elemental composition of the tetrakis(triphenylstannyl) silicate compound in a powder form was confirmed by XPS, and the results are shown in the following Table 1 and FIG. 4.

TABLE 1

| Name | Atomic % |
|---|---|
| C1s | 70.28 |
| N1s | 0.65 |
| O1s | 23.69 |
| Si2p | 1.4 |
| Cl2p | 0.16 |
| Sn3d3 | 0 |
| Sn3d5 | 3.83 |

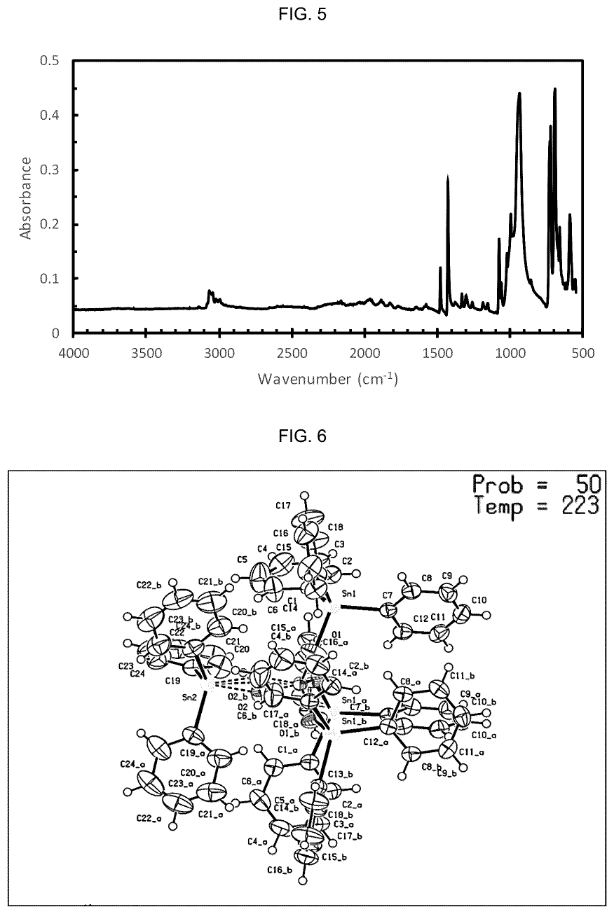

In FIG. 5, the FT-IR spectrum of the tetrakis(triphenylstannyl) silicate compound is shown. A small amount of the tetrakis(triphenylstannyl) silicate compound was dissolved in chloroform, and the solvent was slowly evaporated at room temperature to make a single crystal, which was measured.

In FIG. 6, the molecular structure of the tetrakis(triphenylstannyl) silicate compound of the single crystal analyzed by SC-XRD is shown.

### [Example 2] Synthesis of tetrakis(trimethylstannyl) Silicate Compound

In the same manner as in Example 1, a solution of 1.0 g (5.19 mmol) of trimethylchlorotin instead of triphenylchlorotin dissolved in 50 mL of tetrahydrofuran and the tetrakis(tetramethylammonium) silicate solution prepared according to Preparation Example 4 were slowly added with a dropping funnel at 75° C. and the reaction was performed for 8 hours. After the reaction was completed, a white solid obtained by recrystallization using tetrahydrofuran was recrystallized three times to obtain 0.6 g (0.82 mmol, yield: 63.1%) of a white crystal. As a result of 500 MHz H-NMR analysis, a Sn—CH₃ peak at 0.67 ppm (s, 36H) was confirmed.

### [Example 3] Synthesis of tetrakis(n-butyldimethylstannyl) Silicate Compound

In the same manner as in Example 1, a solution of 1.3 g (5.19 mmol) of n-butyldimethylchlorotin instead of triphenylchlorotin dissolved in 50 mL of tetrahydrofuran and the tetrakis(tetramethylammonium) silicate solution prepared according to Preparation Example 1 were slowly added with a dropping funnel at 75° C. and the reaction was performed for 8 hours. Thereafter, recrystallization was performed using tetrahydrofuran to obtain 0.95 g (0.77 mmol, yield: 59.1%) of a white crystal. As a result of 500 MHz H-NMR analysis, peaks of Sn—CH₃ at 0.67 ppm (s, 24H), Sn—CH₂— at 0.92 ppm (t, 8H), CH₃—CH₂ at 1.33 ppm (m, 8H), —CH₂—CH₂— at 1.58 ppm (m, 8H), and —CH₂—CH₃ at 1.63 ppm (t, 12H) were confirmed.

### [Example 4] Synthesis of tetrakis(tri-n-propylstannyl) Silicate

1.3 g (5.19 mmol) of tri-n-propylchlorotin and 50 ml of tetrahydrofuran were added in the same manner as in Example 1. While the solution was stirred at 75° C. with a mechanical stirrer, the tetrakis(tetramethylammonium) silicate solution prepared according to Preparation Example 3 was slowly added with a dropping funnel and the reaction was performed for 8 hours. The product was extracted using tetrahydrofuran and recrystallized to obtain 0.8 g (0.75 mmol, yield: 57.9%) of a white crystal. As a result of 500 MHz H-NMR analysis, peaks of —CH₂—CH₃ at 0.94 ppm (t, 36H), CH₃—CH₂ at 1.4 ppm (m, 24H), and Sn—CH₂— at 1.63 ppm (t, 24H) were confirmed.

### [Example 5] Synthesis of tetrakis(tri-n-pentylstannyl) Silicate

1.9 g (5.19 mmol) of tri-n-pentylchlorotin and 50 mL of tetrahydrofuran were added in the same manner as in Example 1. While the solution was stirred at 75° C. with a mechanical stirrer, the tetrakis(tetramethylammonium) silicate solution prepared according to Preparation Example 1 was slowly added with a dropping funnel and the reaction was performed for 8 hours. The product was extracted using tetrahydrofuran and recrystallized to obtain 0.98 g (0.80 mmol, yield: 62.3%) of a white crystal. As result of 500 MHz H-NMR analysis, peaks of Sn—CH₂— at 0.88 ppm (m, 24H), CH₃—CH₂— at 1.28 ppm (m, 24H), CH₃—CH₂—CH₂— at 1.29 ppm (m, 24H), Sn—CH₂—CH₂— at 1.58 ppm (m, 24H), and —CH₂—CH₃ at 1.63 ppm (t, 36H) were confirmed.

### [Example 6] Synthesis of tetrakis(tri-n-octylstannyl) Silicate

2.6 g (5.19 mmol) of tri-n-octylchlorotin and 50 ml of tetrahydrofuran were added in the same manner as in Example 1. While the solution was stirred at 75° C. with a mechanical stirrer, the tetrakis(tetramethylammonium) silicate solution prepared according to Preparation Example 1 was slowly added with a dropping funnel and the reaction was performed at 75ºC for 8 hours. The product was extracted using tetrahydrofuran and recrystallized to obtain 1.4 g (0.72 mmol, yield: 55.8%) of a white crystal. As result of 500 MHz H-NMR analysis, peaks of Sn—CH₂— at 0.88 ppm (m, 24H), —CH₂—CH₂— at 1.26-1.29 ppm (m, 120H), Sn—CH₂—CH₂— at 1.58 ppm (m, 24H), CH₂—CH₃ at 1.63 ppm (t, 36H) were confirmed.

### [Example 7] Synthesis of tetrakis(tricyclohexylstannyl) Silicate

2.1 g (5.19 mmol) of tricyclohexylchlorotin and 50 mL of tetrahydrofuran were added in the same manner as in Example 1. While the solution was stirred at 75° C. with a mechanical stirrer, the tetrakis(tetramethylammonium) silicate solution prepared according to Preparation Example 3 was slowly added with a dropping funnel and the reaction was performed for 8 hours. The product was extracted using tetrahydrofuran and recrystallized to obtain 1.3 g (0.82 mmol, yield: 63.6%) of a white crystal. As a result of 500 MHZ H-NMR analysis, a Sn-CyH peak at 1.4-1.6 ppm (m, 132H) was confirmed.

### [Example 8] Synthesis of tetrakis(tri-p-tolylstannyl) Silicate

2.2 g (5.19 mmol) of tri-p-tolylchlorotin and 50 ml of tetrahydrofuran were added in the same manner as in Example 1. While the solution was stirred at 75° C. with a mechanical stirrer, the tetrakis(tetramethylammonium) silicate solution prepared according to Preparation Example 2 was slowly added with a dropping funnel and the reaction was performed for 8 hours. The product was extracted using tetrahydrofuran and recrystallized to obtain 1.3 g (0.81 mmol, yield: 62.3%) of a white crystal. As a result of 500 MHZ H-NMR analysis, peaks of Sn-Ph at 7.16-7.43 ppm (m, 48H) and Ph-CH₃ at 2.37 ppm (s, 36H) were confirmed.

### [Example 9] Synthesis of tetrakis(tribenzylstannyl) Silicate

2.2 g (5.19 mmol) of tribenzylchlorotin and 50 mL of tetrahydrofuran were added in the same manner as in Example 1. While the solution was stirred at 75° C. with a mechanical stirrer, the tetrakis(tetramethylammonium) silicate solution prepared according to Preparation Example 2 was slowly added with a dropping funnel and the reaction was performed at 75° C. for 8 hours. The product was extracted using tetrahydrofuran and recrystallized to obtain 1.26 g (0.76 mmol, yield: 58.8%) of a white crystal. As a result of 500 MHZ H-NMR analysis, peaks of CH₂-Ph at 7.16-7.25 ppm (m, 60H) and Sn—CH₂ at 2.6 ppm (s, 24H) were confirmed.

### [Example 10] Synthesis of tetrakis(diphenyl(t-butyl)stannyl) Silicate

In the same manner as in Example 1, while a solution of 1.9 g (5.19 mmol) of diphenyl(t-butyl)chlorotin dissolved in 50 ml of tetrahydrofuran was stirred with a mechanical stirrer at 75° C., the tetrakis(tetramethylammonium) silicate solution prepared according to Preparation Example 2 was slowly added with a dropping funnel to perform the reaction for 8 hours. The product was extracted using tetrahydrofuran and recrystallized to obtain 0.91 g (0.65 mmol, yield: 50.0%) of a white crystal. As a result of 500 MHz H-NMR analysis, peaks of Sn-Ph at 7.41-7.48 ppm (m, 40H) and C—CH₃ at 1.0 ppm (s, 36H) were confirmed.

### [Example 11] Synthesis of tetrakis(phenyl(dit-butyl)stannyl) Silicate

1.8 g (5.19 mmol) of phenyl(dit-butyl)chlorotin and 50 mL of tetrahydrofuran were added in the same manner as in Example 1. While the solution was stirred at 75° C. with a mechanical stirrer, the tetrakis(tetramethylammonium) silicate solution prepared according to Preparation Example 1 was slowly added with a dropping funnel and the reaction was performed at 75° ° C. for 8 hours. The product was extracted using tetrahydrofuran and recrystallized to obtain 0.85 g (0.64 mmol, yield: 49.5%) of a white crystal. As a result of 500 MHz H-NMR analysis, peaks of Sn-Ph at 7.41-7.48 ppm (m, 20H) and C—CH₃ at 1.0 ppm (s, 72H) were confirmed.

### [Example 12] Synthesis of tetrakis(trimethylstannyl) Silicate (High Pressure Reaction)

1.0 g (5.19 mmol) of trimethylchlorotin, the tetrakis(tetramethylammonium) silicate solution prepared according to Preparation Example 1, and 50 ml of tetrahydrofuran were added to a reaction vessel (75 mL high pressure reactor), and the reaction was performed at 70 bar, 100° C. for 5 hours. The product was extracted using tetrahydrofuran and recrystallized to obtain 0.66 g (0.88 mmol, yield: 68.3%) of a white crystal.

As a result of 500 MHZ H-NMR analysis, a Sn—CH₃ peak at 0.67 ppm (s, 36H) was confirmed.

### [Example 13] Synthesis of Triphenylstannyl Silicate (High Pressure Reaction)

2.0 g (5.19 mmol) of triphenylchlorotin, the tetrakis(tetramethylammonium) silicate solution prepared according to Preparation Example 1, and 50 ml of tetrahydrofuran were added to a reaction vessel (75 mL high pressure reactor), and the reaction was performed at 70 bar, 100° C. for 5 hours. The product was extracted using tetrahydrofuran and recrystallized to obtain 1.3 g (0.84 mmol, yield: 65.1%) of a white crystal.

As a result of 500 MHZ H-NMR analysis, a Sn-Ph peak at 7.30-7.49 ppm (m, 60H) was confirmed.

### [Example 14] Synthesis of tetrakis(triacetoxystannyl) Silicate

A reflux condenser, a heating mantle, and a stirrer were installed in a 50 ml round bottom flask having two spouts. 1 g (0.67 mmol) of tetrakis(triphenylstannyl) silicate, 10.5 g (174.86 mmol) of acetic acid, and 1.2 g (11.90 mmol) of anhydrous acetic acid were added to a reaction vessel, and the reaction was performed at 90° C. for 16 hours while stirring with a mechanical stirrer. A volatile material was depressurized and distilled at room temperature to obtain 0.8 g (0.06 mmol, yield: 94%) of a residual white solid.

The synthesized product was analyzed by 1H-NMR, MALDI-TOF.

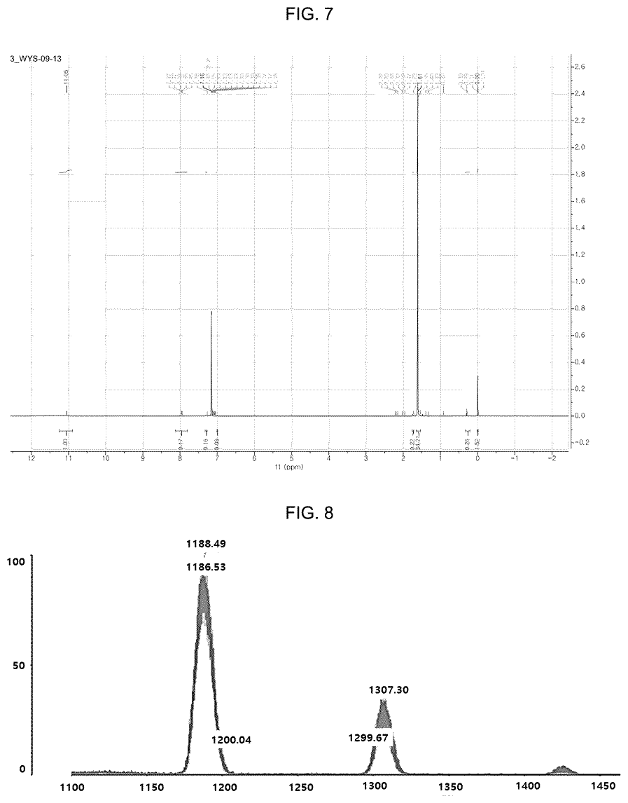

As a result of 500 MHZ H-NMR analysis, a CH₃ peak of an acetoxy group at 1.61 ppm (m, 36H) was confirmed. Further, a peak of tetrakis(triacetoxystannyl) silicate from which an acetoxy group had been released having a molecular weight of 1187 was confirmed by MALDI-TOF, and is shown in FIGS. 7 and 8.

### [Example 15] Synthesis of tetrakis(trichlorostannyl) Silicate

1 g (0.67 mmol) of tetrakis(triphenylstannyl) silicate, 2 g (7.69 mmol) of tin chloride (IV), and 11.6 g (125.89 mmol) of toluene were added to a reaction vessel (75 mL high pressure reactor), and the reaction was performed at 70 bar, 100° C. for 5 hours. A volatile material was depressurized and distilled to obtain 0.8 g (0.64 mmol, yield: 95.6%) of a residual white solid. A part of the product was taken and treated with a methyl Grignard reagent, and as a result of 500 MHZ H-NMR analysis, a Sn—CH₃ peak at 0.67 ppm (s, 36H) was confirmed.

### [Example 16] Synthesis of tetrakis(trimethoxystannyl) Silicate

A reflux condenser and a stirrer were installed in a 50 ml round bottom flask having two spouts. 0.8 g (0.64 mmol) of tetrakis(trichlorostannyl) silicate and 8 mL of tetrahydrofuran were added to a reaction vessel. While the solution was stirred with a mechanical stirrer, 0.5 g (2.82 mmol) of a 30% methanol solution of sodium methylate (DUKSAN PURE CHEMICALS CO., LTD.) was slowly added with a dropping funnel and the reaction was performed for 8 hours. A volatile material was removed by depressurization and distillation at room temperature to obtain 0.6 g (0.63 mmol, yield: 99%) of a white solid. As a result of 500 MHZ H-NMR, a O—CH₃ peak at 3.39 ppm (s, 36H) was confirmed.

### [Example 17] Synthesis of tetrakis(triethoxystannyl) Silicate

A reflux condenser and a stirrer were installed in a 50 ml round bottom flask having two inlets. 0.8 g (0.64 mmol) of tetrakis(trichlorostannyl) silicate and 8 mL of tetrahydrofuran were added to a reaction vessel. While the solution was stirred with a mechanical stirrer, 0.9 g (2.82 mmol) of a 21% ethanol solution of sodium ethoxide (Sigma-Aldrich, USA) was slowly added with a dropping funnel and the reaction was performed for 8 hours. A volatile material was removed by depressurization and distillation at room temperature to obtain 0.6 g (0.58 mmol, yield: 90%) of a white solid. As a result of 500 MHZ H-NMR analysis, peaks of CH₂—CH₃ at 1.10 ppm (t, 36H) and O—CH₂ at 3.57 ppm (m, 24H) were confirmed.

### [Example 18] Synthesis of tetrakis(dichloro(t-butyl)stannyl) Silicate

0.9 g (0.67 mmol) of tetrakis(diphenyl(t-butyl))stannyl silicate, 2 g (7.69 mmol) of tin chloride (IV), and 11.6 g (125.89 mmol) of toluene were added to a reaction vessel (75 mL high pressure reactor), and the reaction was performed at 70 bar, 100° C. for 5 hours. A volatile material was removed by depressurization and distillation to obtain 0.7 g (0.66 mmol, yield: 98.3%) of a white solid. As a result of 500 MHz H-NMR, a C—CH₃ peak at 1.0 ppm (s, 36H) was confirmed.

### [Example 19] Synthesis of tetrakis(dihydroxy(t-butyl)stannyl) Silicate

A reflux condenser and a stirrer were installed in a 50 ml round bottom flask having two spouts. 0.7 g (0.64 mmol) of tetrakis(dichloro(t-butyl)stannyl) silicate and 8 mL of tetrahydrofuran were added to a reaction vessel. While the solution was stirred with a mechanical stirrer, 0.9 g (2.82 mmol) of a 50% sodium hydroxide solution (Sigma-Aldrich, USA) was slowly added with a dropping funnel and the reaction was performed for 8 hours. A volatile material was removed by depressurization and distillation at room temperature to obtain 0.6 g (0.60 mmol, yield: 93%) of a white solid. As a result of 500 MHz H-NMR analysis, peaks of C—CH₃ at 1.0 ppm (s, 36H) and Sn—OH at 4.2 ppm (s, 8H) were confirmed.

### [Experimental Example 1] Solubility Experiment of tetrakis(triphenylstannyl) Silicate

For manufacturing a thin film including the tetrakis(triphenylstannyl) silicate compound prepared in Example 1, solubility in various solvents was experimented and is shown in the following Tables 2 and 3:

TABLE 2

| | | | | | Methyl | Propylene | Propylene |
|---|---|---|---|---|---|---|---|
| | | | gamma- | Ethyl | isobutyl | glycol | glycol methyl |
| | | | Butyrolactone | lactate | ketone | methyl ether | ether acetate |
| Solvent | Chloroform | THF | (GBL) | (EL) | (MIBK) | (PGME) | (PGMEA) |
| Solubility | ◯ | ◯ | Δ | Δ | X | X | X |

TABLE 3

| | | | Ethyl | | Whether forming |
|---|---|---|---|---|---|
| | | | lactate | Methyl isobutyl | thin film is |
| | Chloroform | Pyridine | (EL) | ketone (MIBK) | possible |
| 1 | 1 | | | | Δ |
| 2 | | 1 | | | ◯ |
| 3 | | | 1 | | X |
| 4 | 8 | | 2 | | X |
| 5 | 8 | | | 2 | X |
| 6 | 9 | | 1 | | ◯ |
| 7 | 9 | | | 1 | X |

From Table 2, it was confirmed that the tetrakis(triphenylstannyl) silicate compound had highest solubilites in chloroform and tetrahydrofuran.

Table 3 shows a volume ratio of the coating solvent, and it was confirmed that the thin film was able to be formed in pyridine, chloroform, or a cosolvent system of chloroform and ethyl lactate at 9:1.

### [Example 20] Exposure of tetrakis(triphenylstannyl) Silicate to Electron Beam

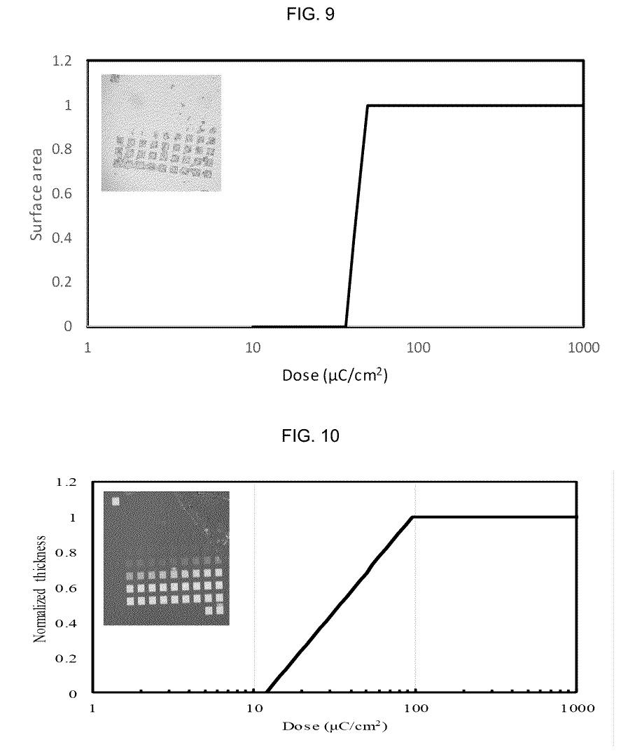

0.1 g of tetrakis(triphenylstannyl) silicate prepared in Example 1 was dissolved in 2 mL of chloroform to prepare a 2% coating solution, and a silicon substrate was coated with a thin film by spin coating (300 rpm 1 s, 3,000 rpm 20 s) and heated at 85° C. for 1 minute to remove the solvent. The manufactured thin film was irradiated with light at an exposure amount of 1-789 μC/cm² using an electron beam, exposed to light at 85° C. for 1 minute, heated (PEB), soaked in a 2.38% tetramethylammonium hydroxide (TMAH) solution, and then developed. The electron beam irradiation amount and the results are shown in FIG. 9.

### [Example 21] Exposure of tetrakis(trimethylstannyl) Silicate to Electron Beam

The process was performed in the same manner as in Example 20, except that tetrakis(trimethylstannyl) silicate prepared in Example 2 was used instead of tetrakis(triphenylstannyl) silicate. The electron beam irradiation amount and the results are shown in FIG. 10.

### [Example 22] Exposure of tetrakis(triacetoxystannyl) Silicate to Electron Beam

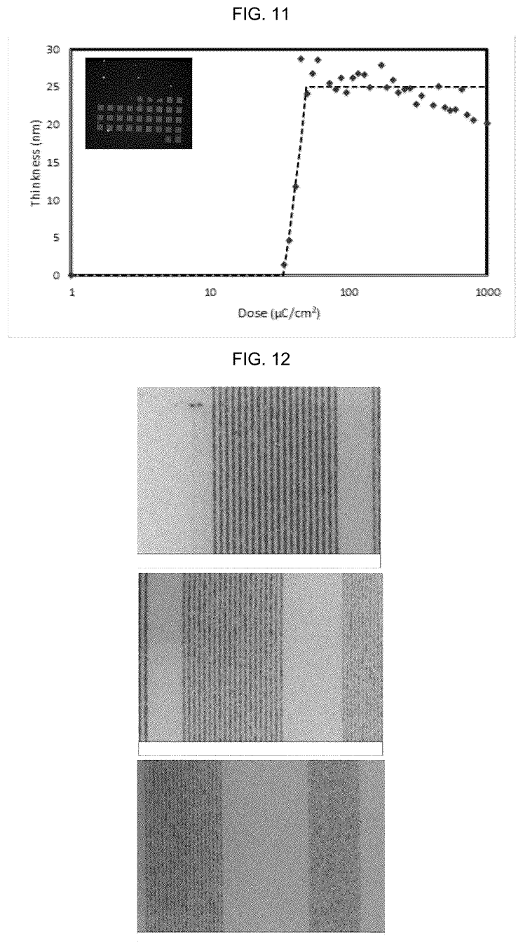

The process was performed in the same manner as in Example 20, except that tetrakis(triacetoxystannyl) silicate prepared in Example 14 was used instead of tetrakis(triphenylstannyl) silicate and ethyl lactate was used instead of chloroform. The electron beam irradiation amount and the results are shown in FIG. 11.

### [Example 23] electron beam line patterning of tetrakis(triacetoxystannyl) Silicate

A 5 wt % tetrakis(triacetoxystannyl) silicate solution was prepared using ethyl lactate as a solvent, and a thin film was manufactured on a silicon substrate by spin coating (500 rpm 5 s, 3,000 rpm 30 s) and heated at 115ºC for 3 minutes to remove the solvent. A line pattern with half pitches at 50, 40, 30, and 20 nm was patterned with electron beam lithography. The thin film was exposed to light at 115° C. for 3 minutes, heated (PEB), soaked in a 2.38% TMAH solution, and then developed. All patterns were confirmed at an exposure amount of 700 μC/cm². The results are shown in FIG. 12.

### [Example 24] Organic Acid Stabilization of tetrakis(triacetoxystannyl) Silicate

A solution of 70% ethyl lactate and 30% acetic acid was used to prepare a 5 wt % tetrakis(triacetoxystannyl) silicate solution, and a thin film was manufactured on a silicon substrate by spin coating (500 rpm 5 s, 3,000 rpm 30 s) and heated at 115° C. for 3 minutes to remove the solvent. The manufactured thin film was irradiated with light at an exposure amount of 1-789 μC/cm² using an electron beam, exposed to light at 85° C. for 1 minute, heated (PEB), soaked in a 2.38% tetramethylammonium hydroxide (TMAH) solution, and then developed. A negative tone photoresist was confirmed, and a D100 value of 106 μC/cm² was confirmed.

Since the photoresist composition included acetic acid, stability of tetrakis(triacetoxystannyl) silicate in water was able to be improved. When water was added at 5% to a 5% tetrakis(triacetoxystannyl) silicate solution, it was confirmed that precipitation occurred immediately. However, when acetic acid was added, precipitation was able to be prevented. It was confirmed that precipitation occurred after 3 minutes in a 10% acetic acid solution, after 3 hours in a 20% solution, and after 5 days in a 30% solution. Besides, the amount of precipitation was decreased as the acetic acid was added. Regarding a large amount of acetic acid, since a hydrolysis rate of an acetoxy group decreased according to le Chatelier's law, stability in water was improved.

A photoresist composition including an organostannyl silicate compound according to the present disclosure may implement excellent etching resistance and light sensitivity, and a photoresist pattern using the composition may be formed at a very small thickness even in an ultrafine pattern, and also may form a high-quality photoresist pattern having excellent resolution and sensitivity.

In addition, since a method for preparing an organostannyl silicate compound according to the present disclosure may selectively synthesize various organic substituents and does not need a separate catalyst or high pressure, the process is relatively simple and an organostannyl silicate compound in an efficiently high yield may be prepared, and thus, the method has a very high industrial use value.

As described above, the method for preparing an organostannyl silicate compound according to the present disclosure may efficiently produce an organostannyl silicate compound to which various organic substituents are bonded with a high yield. In addition, since a photoresist composition including the organostannyl silicate compound according to the present disclosure may implement both excellent light sensitivity and etching resistance, a high-quality semiconductor device may be manufactured using the composition, and thus, the composition is very useful.

The above description of the present disclosure is for illustration, and those with ordinary knowledge in the art will appreciate that various modifications and alterations may be easily made without departing from the spirit or essential feature of the present disclosure. Therefore, it should be understood that the exemplary embodiments described above are not restrictive, but illustrative in all aspects.

What is claimed is:

1. An organostannyl silicate compound represented by the following Chemical Formula 1: 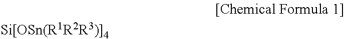
wherein
R¹ to R³ are independently of one another substituted or unsubstituted C6-C12 aryl, straight-chain or branched-chain C1-C10 alkyl, C3-C7 cycloalkyl, C2-C6 alkenyl, C6-C12 arylC1-C5 alkyl, hydroxyl, C1-C5 alkoxy, C1-C5 alkylcarbonyloxy, or halogen.

2. The organostannyl silicate compound of claim 1, wherein R¹ to R³ are phenyl.

3. The organostannyl silicate compound of claim 1, wherein R¹ to R³ are independently of one another C1-C5 alkylcarbonyloxy.

4. The organostannyl silicate compound of claim 1, wherein R¹ to R³ are independently of one another straight-chain or branched-chain C1-C7 alkyl.

5. A photoresist composition comprising an organostannyl silicate compound represented by the following Chemical Formula 1: 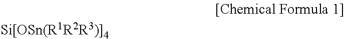
wherein
R¹ to R³ are independently of one another substituted or unsubstituted C6-C12 aryl, straight-chain or branched-chain C1-C10 alkyl, C3-C7 cycloalkyl, C2-C6 alkenyl, C6-C12 arylC1-C5 alkyl, hydroxyl, C1-C5 alkoxy, C1-C5 alkylcarbonyloxy, or halogen.

6. The photoresist composition of claim 5, wherein R¹ to R³ are phenyl.

7. The photoresist composition of claim 5, wherein R¹ to R³ are independently of one another C1-C5 alkylcarbonyloxy.

8. The photoresist composition of claim 5, wherein R¹ to R³ are independently of one another straight-chain or branched-chain C1-C7 alkyl.

9. The photoresist composition of claim 7, further comprising acetic acid.

10. The photoresist composition of claim 9, wherein the acetic acid is comprised at a weight ratio of 0.1 to 50 of the photoresist composition.

11. The photoresist composition of claim 5, wherein the photoresist is a photoresist for extreme ultraviolet rays (EUV).

12. The photoresist composition of claim 5, wherein the organostannyl silicate compound is comprised at a weight ratio of 0.1 to 50 of the photoresist composition.

13. A method for forming a photoresist pattern, the method comprising:
(a) applying the photoresist composition of claim 5 to a substrate to form a thin film and heating the thin film;
(b) exposing the thin film to light;
(c) heating the light-exposed thin film; and
(d) developing the thin film using a developing solution.

14. A semiconductor device manufactured by the method of forming a photoresist pattern of claim 13.
